(19) United States
(12) Patent Application Publication
(10) Pub. No.: US 2025/0294892 A1
(43) Pub. Date: Sep. 18, 2025

(54) SEMICONDUCTOR DEVICE AND METHOD OF MANUFACTURING THE SAME

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/780,804

(22) Filed: Jul. 23, 2024

(30) Foreign Application Priority Data
Mar. 18, 2024 (KR) 10-2024-0037263

(51) Int. Cl. H01L 27/02; H10B 41/41; H10B 43/40

(52) U.S. Cl. CPC H10D 89/611; H10B 41/41; H10B 43/40

(57) ABSTRACT

Provided herein may be a semiconductor device and a method of manufacturing the same. The semiconductor device may include a substrate including a first region and a second region, a transistor including a gate insulating layer and a gate electrode that are stacked over the first region of the substrate, a first diode, at least a portion of the first diode being formed in the second region of the substrate, an insulating layer disposed on the substrate, a second diode disposed in the insulating layer to be spaced apart from the substrate, and interconnections connected to the first diode, the second diode, and the gate electrode, respectively.

### CROSS-REFERENCE TO RELATED APPLICATION

The present application claims priority under 35 U.S.C. § 119(a) to Korean patent application number 10-2024-0037263 filed on Mar. 18, 2024, in the Korean Intellectual Property Office, the entire contents of which application is incorporated herein by reference.

### BACKGROUND

### 1. Technical Field

Various embodiments of the present disclosure generally relate to a semiconductor device and a method of manufacturing the semiconductor device, and more particularly to a semiconductor device including a transistor and an interconnection and a method of manufacturing the semiconductor device.

### 2. Related Art

As electronic devices using semiconductor memory devices become smaller, a decrease in the area of semiconductor memory devices is required. As part of the efforts to meet this requirement, a peripheral under cell (PUC) structure in which a peripheral circuit structure that controls the operation of memory cells is disposed under the memory cells is proposed.

### SUMMARY

An embodiment of the present disclosure may provide for a semiconductor device. The semiconductor device may include a substrate including a first region and a second region, a transistor including a gate insulating layer and a gate electrode that are stacked over the first region of the substrate, a first diode, at least a portion of the first diode being formed in the second region of the substrate, an insulating layer disposed on the substrate, a second diode disposed in the insulating layer to be spaced apart from the substrate, and interconnections connected to the first diode, the second diode, and the gate electrode, respectively.

An embodiment of the present disclosure may provide for a method of manufacturing a semiconductor device. The method may include forming a transistor including a gate insulating layer and a gate electrode that are stacked over a first region of a substrate, forming a first diode, wherein at least a portion of the first diode is formed in a second region of the substrate, forming a first insulating layer that covers the transistor and the first diode on the substrate, forming a first interconnection that penetrates the first insulating layer, the first interconnection connecting the gate electrode to the first diode, forming a second diode in the first insulating layer, and forming a second interconnection that connects the first interconnection to the second diode.

### BRIEF DESCRIPTION OF THE DRAWINGS

FIG. 1 is a diagram illustrating a semiconductor device according to an embodiment of the present disclosure.

FIG. 2 is a diagram schematically illustrating a semiconductor device according to an embodiment of the present disclosure.

FIGS. 3A and 3B are views illustrating a peripheral circuit structure of a semiconductor device according to an embodiment of the present disclosure.

FIGS. 4A to 4L are views illustrating a method of manufacturing a peripheral circuit structure of a semiconductor device according to an embodiment of the present disclosure.

FIG. 5 is a diagram illustrating a memory card system to which a semiconductor device according to the present disclosure is applied.

FIG. 6 is a diagram illustrating a solid state drive (SSD) system to which a semiconductor device according to the present disclosure is applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Hereinafter, various embodiments of the present disclosure will be described in detail with reference to the accompanying drawings in which embodiments of the present disclosure are shown so that those skilled in the art to which the present disclosure pertains can easily practice the technical spirit of the present disclosure.

Various embodiments of the present disclosure are directed to a semiconductor device capable of reducing damage to a peripheral circuit structure and a method of manufacturing the semiconductor device.

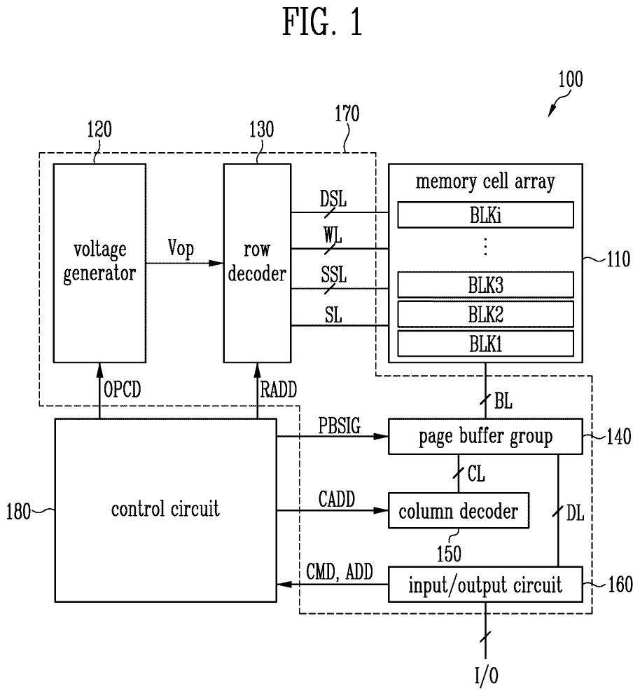

FIG. 1 is a diagram illustrating a semiconductor device according to an embodiment of the present disclosure.

Referring to FIG. 1, a semiconductor device 100 may include a memory cell array 110, a peripheral circuit 170, and a control circuit 180. In the present disclosure, the semiconductor device 100 may be a memory device.

The memory cell array 110 may include first to i-th memory blocks BLK1 to BLKi. Each of the first to i-th memory blocks BLK1 to BLKi may include memory cells capable of storing data. Drain select lines DSL, word lines WL, source select lines SSL, and a source line SL may be coupled to each of the first to i-th memory blocks BLK1 to BLKi, and bit lines BL may be coupled in common to the first to i-th memory blocks BLK1 to BLKi.

Each of the first to i-th memory blocks BLK1 to BLKi may be formed to have a two-dimensional (2D) structure or a three-dimensional (3D) structure. Each memory block having a 2D structure may include memory cells arranged in parallel on a substrate. Each memory block having a 3D structure may include memory cells stacked on a substrate in a vertical direction. In the present embodiment, although the memory blocks formed to have a 3D structure are described for convenience of description, the present embodiment may also be applied to memory blocks having a 2D structure.

According to a program scheme, each memory cell may store 1 bit of data or 2 or more bits of data. For example, a scheme for storing 1 bit of data in one memory cell may be referred to as a single-level cell (SLC) scheme, and a scheme for storing 2 bits of data in one memory cell may be referred to as a multi-level cell (MLC) scheme. A scheme for storing 3 bits of data in one memory cell may be referred to as a triple-level cell (TLC) scheme, and a scheme for storing 4 bits of data in one memory cell may be referred to as a quad-level cell (QLC) scheme. In addition, 5 or more bits of data may be stored in one memory cell.

The peripheral circuit 170 may perform a program operation that stores data in the memory cell array 110, a read operation that outputs data stored in the memory cell array 110, and an erase operation that erases data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to a selected word line, among the word lines WL, during a program operation and may be used to increase the threshold voltages of memory cells coupled to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or source select transistors. For example, the turn-off voltage may be set to 0 V. The precharge voltages may be voltages higher than 0 V and may be applied to the bit lines during a read operation. The verify voltages may be used for a verify operation that determines whether the threshold voltages of selected memory cells have increased to a target level. The verify voltages may be set to various levels according to the target level and may be applied to a selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines, among the word lines WL, during a program or read operation and may be used to turn on memory cells coupled to the unselected word lines. The erase voltages may be used during an erase operation that erases the memory cells included in the selected memory block and may be applied to the source line SL.

The row decoder 130 may transfer the operating voltages Vop to the drain select lines DSL, the word lines WL, the source select lines SSL, and the source line SL, which are coupled to a memory block selected according to the row address RADD. For example, the row decoder 130 may be coupled to the voltage generator 120 through global lines and may be coupled to the first to i-th memory blocks BLK1 to BLKi through the drain select lines DSL, the word lines WL, the source select lines SSL, and the source line SL.

The page buffer group 140 may include page buffers (not illustrated) coupled to the first to i-th memory blocks BLK1 to BLKi, respectively. The page buffers (not illustrated) may be coupled to the first to i-th memory blocks BLK1 to BLKi through the bit lines BL. During a read operation, the page buffers (not illustrated) may sense the currents or voltages of bit lines varying with the threshold voltages of the selected memory cells in response to page buffer control signals PBSIG and may temporarily store the sensed data.

The column decoder 150 may be configured such that data is transferred between the page buffer group 140 and the input/output circuit 160 in response to a column address CADD. For example, the column decoder 150 may be coupled to the page buffer group 140 through column lines CL and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180 and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

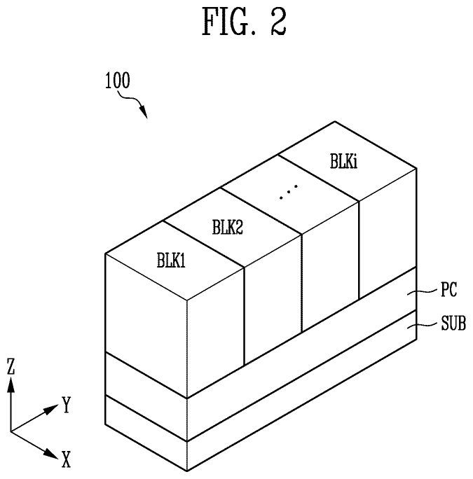

FIG. 2 is a diagram schematically illustrating a semiconductor device according to an embodiment of the present disclosure.

Referring to FIG. 2, the semiconductor device 100 (e.g., memory device) may include a peripheral circuit structure PC disposed on a substrate SUB and memory blocks BLK1 to BLKi. The memory blocks BLK1 to BLKi may overlap with the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC may include a row decoder 130, a column decoder 150, a page buffer group 140, a control circuit 180, etc., which constitute a circuit for controlling the operation of the memory blocks BLK1 to BLKi. For example, the peripheral circuit structure PC may include a transistor (e.g., an NMOS transistor or a PMOS transistor), a diode (e.g., a PN diode), a resistor, a capacitor, etc., which are electrically connected to the memory blocks BLK1 to BLKi. The peripheral circuit structure PC may be disposed under the memory blocks BLK1 to BLKi. The peripheral circuit structure PC may be disposed on the substrate SUB. Unlike the configuration illustrated in FIG. 2, the peripheral circuit structure PC may include a portion of the substrate SUB. For example, a portion of the transistor (or a portion of the diode) included in the peripheral circuit structure PC may be formed in the substrate SUB.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors which are connected in series by a cell plug. Each of the select lines may be used as a gate electrode of a select transistor corresponding thereto, and each of the word lines may be used as a gate electrode of a memory cell corresponding thereto.

In an embodiment, unlike the configuration illustrated in FIG. 2, the peripheral circuit structure PC may be disposed in partial areas of the substrate SUB that do not overlap with the memory blocks BLK1 to BLKi. For example, the peripheral circuit structure PC and the memory blocks BLK1 to BLKi may be disposed in respective areas that do not overlap with each other on the substrate SUB.

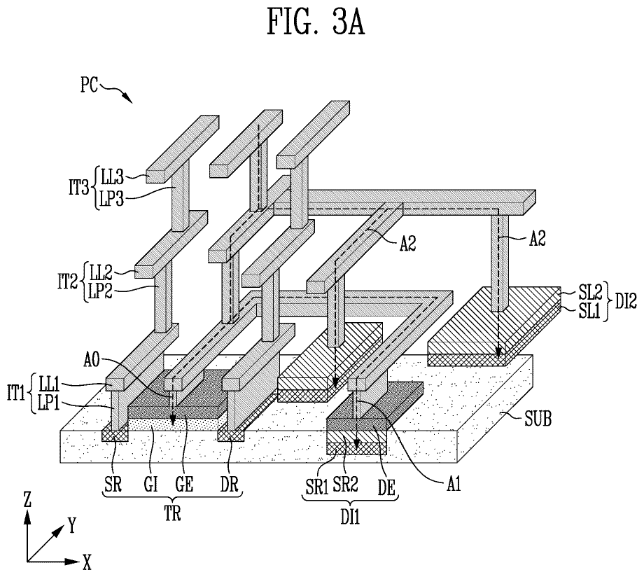

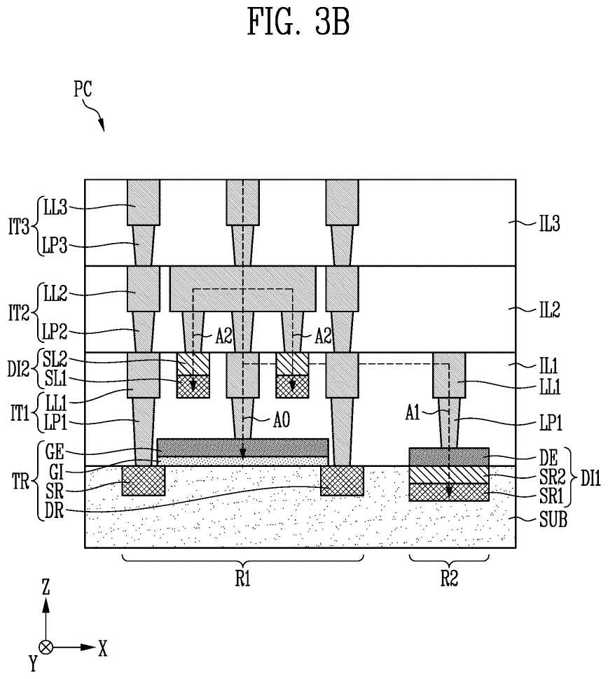

FIGS. 3Aa and 3B are views illustrating a peripheral circuit structure of a semiconductor device according to an embodiment of the present disclosure.

FIGS. 3A and 3B illustrate a portion of the peripheral circuit structure PC included in the semiconductor device (e.g., the semiconductor device 100 of FIGS. 1 and 2) according to the present disclosure. It may be understood that a portion of the peripheral circuit structure PC described in FIG. 2 is illustrated in FIGS. 3A and 3B. Further, although an illustration of a memory cell array (e.g., the memory cell array 110 of FIG. 1) is omitted in FIGS. 3A and 3B, it may be understood that the memory cell array is disposed over the peripheral circuit structure PC of FIGS. 3A and 3B.

Referring to FIGS. 3A and 3B, a substrate SUB may include a first region R1 and a second region R2. A transistor TR may be formed in the first region R1 of the substrate SUB, and a first diode DI1 may be formed in the second region R2 of the substrate SUB. The first diode DI1 may be disposed to be spaced apart from the transistor TR in an X direction. Because the first region R1 and the second region R2 of the substrate SUB are separated for convenience of description, they might not be physically separated from each other, or alternatively, a boundary therebetween might not be clearly observed.

The transistor TR may be disposed in the first region R1 of the substrate SUB. For example, at least a portion of the transistor TR is disposed in the first region R1 of the substrate SUB, and the other portion of the transistor TR is disposed over the first region R1 of the substrate SUB. The transistor TR may include a gate insulating layer GI and a gate electrode GE that are stacked over the first region R1 of the substrate SUB. The gate electrode GE may be disposed on the gate insulating layer GI. The gate insulating layer GI may contain an insulating material (e.g., an oxide layer). The gate electrode GE may contain a conductive material (e.g., a metal material). Also, the transistor TR may include a source region SR and a drain region DR that are formed in the first region R1 of the substrate SUB. When viewed on an x-y plane, the source region SR may be disposed adjacent to one side (e.g., in a −X direction) of the gate electrode GE, and the drain region DR may be disposed adjacent to the other side (e.g., in a +X direction) of the gate electrode GE. A portion of the source region SR and a portion of the drain region DR may or might not individually overlap with a portion of the gate electrode GE. Each of the source region SR and the drain region DR may contain impurities of a first type (e.g., an N type). Alternatively, each of the source region SR and the drain region DR may contain impurities of a second type (e.g., a P type).

The first diode DI1 may be disposed in the second region R2 of the substrate SUB. For example, at least a portion of the first diode DI1 is disposed in the second region R2 of the substrate SUB, and the other portion of the first diode DI1 is disposed over the second region R2 of the substrate SUB. The first diode DI1 may include a first semiconductor region SR1 and a second semiconductor region SR2 that are formed in the second region R2 of the substrate SUB. The second semiconductor region SR2 may be disposed on the first semiconductor region SR1. The first semiconductor region SR1 may contain impurities of a first type (e.g., N type), and the second semiconductor region SR2 may contain impurities of a second type (e.g., P type). The first diode DI1 may include a diode electrode DE stacked over the second region R2 of the substrate SUB. The diode electrode DE may be disposed on the second semiconductor region SR2. The diode electrode DE may contact the second semiconductor region SR2. The diode electrode DE may overlap with the first and second semiconductor regions SR1 and SR2. The diode electrode DE may contain a conductive material (e.g., a metal material).

Insulating layers IL1, IL2, and IL3 may be disposed on the substrate. In the present disclosure, although the insulating layers IL1, IL2, and IL3 are separately referred to as first to third insulating layers IL1 to IL3, this structure is provided for convenience of description, and the first to third insulating layers IL1 to IL3 might not be physically separated from each other, or alternatively, boundaries thereamong might not be clearly observed.

The first insulating layer IL1 may be formed on the substrate SUB. The first insulating layer IL1 may cover the transistor TR and the first diode DI1. The second insulating layer IL2 may be disposed on the first insulating layer IL1. The third insulating layer IL3 may be disposed on the second insulating layer IL2. Each of the first to third insulating layers IL1 to IL3 may contain an insulating material (e.g., an oxide layer).

Second diodes DI2 may be disposed in the insulating layers IL1, IL2, and IL3. For example, the second diodes DI2 may be disposed in the first insulating layer IL1. The second diodes DI2 may be spaced apart from the substrate SUB. Further, the second diodes DI2 may be spaced apart from the transistor TR and the first diode DI1. Although, in FIGS. 3A and 3B, the positions of the second diodes DI2 are illustrated as being different from each other, the illustrated positions may be included in the scope of the present disclosure as long as the second diodes DI2 are disposed in the insulating layers IL1, IL2, and IL3 to be spaced apart from the substrate SUB.

Each of the second diodes DI2 may include a first semiconductor layer SL1 and a second semiconductor layer SL2 that are disposed in the first insulating layer IL1. The second semiconductor layer SL2 may be disposed on the first semiconductor layer SL1. Each of the first and second semiconductor layers SL1 and SL2 may contain polysilicon. The first semiconductor layer SL1 may contain impurities of a first type (e.g., N type), and the second semiconductor layer SL2 may contain impurities of a second type (e.g., P type).

The peripheral circuit structure PC may include interconnections (e.g., IT1, IT2, and IT3). The interconnections (e.g., IT1, IT2, and IT3) may be connected to the transistor TR, the first diode DI1, and the second diodes DI2, respectively. Each of the interconnections (e.g., IT1, IT2, and IT3) may contain a conductive material (e.g., a metal material, such as tungsten (W), copper (CU), or molybdenum (Mo)). In the present disclosure, it may be understood that the first interconnection IT1, the second interconnection IT2, and the third interconnection IT3 are designated depending on the order of stacking or the order of formation on the substrate SUB.

The first interconnection IT1 may be enclosed by the first insulating layer IL1. The first interconnection IT1 may include first plugs LP1 and first lines LL1. Some of the first plugs LP1 may contact the gate electrode GE, the source region SR, and the drain region DR of the transistor TR, respectively. Further, other first plugs LP1 may contact the diode electrode DE of the first diode DI1. Referring to FIG. 3A, each of the first plugs LP1 may have a shape extending in a Y direction (e.g., a linear shape). Unlike the structure illustrated in FIG. 3A, the first plugs LP1 may have cylindrical shapes or may have various other shapes. The first lines LL1 may contact the first plugs LP1, respectively. The first lines LL1 may contact the top surfaces of the first plugs LP1, respectively. Referring to FIG. 3A, a first line LL1 connected to the gate electrode GE of the transistor TR may be electrically connected to a first line LL1 connected to the first diode DI1.

The second diodes DI2 may be located at the same level as at least a portion of the first interconnection IT1. In an example, in FIG. 3B, the second diodes DI2 may be located at the same level as the first lines LL1. In an example, the second diodes DI2 may be located at the same level as the first plugs LP1. In an example, the second diodes DI2 may be located at the same level as the bottoms of the first lines LL1 and the tops of the first plugs LP1.

The second diodes DI2 may be disposed to be spaced apart from the first interconnection IT1. The second diodes DI2 may be spaced apart from the first plugs LP1. The second diodes DI2 may be spaced apart from the first lines LL1. The first insulating layer IL1 may be disposed between the second diodes DI2 and the first interconnection IT1. The first insulating layer IL1 may be disposed between the second diodes DI2 and the substrate SUB and between the second diodes DI2 and the first interconnection IT1. The second diodes DI2 may be insulated from the substrate SUB and the first interconnection IT1 by the first insulating layer IL1.

The second interconnection IT2 may be enclosed by the second insulating layer IL2. The second interconnection IT2 may be disposed on the first interconnection IT1. The second interconnection IT2 may include second plugs LP2 and second lines LL2.

Some of the second plugs LP2 may contact the first lines LL1. For example, some of the second plugs LP2 may contact the top surfaces of the first lines LL1. Other second plugs LP2 may contact the second diodes DI2. For example, other second plugs LP2 may contact the second semiconductor layers SL2 of the second diodes DI2. The second plugs LP2 may be electrically connected to the first lines LL1 or the second diodes DI2. Each of the second plugs LP2 may have a cylindrical shape, a square pillar shape, or a tapered cylindrical shape. The second plugs LP2 may have various other shapes.

The second lines LL2 may contact the second plugs LP2, respectively. The second lines LL2 may contact the top surfaces of the second plugs LP2. Referring to FIGS. 3A and 3B, a second line LL2 connected to the gate electrode GE of the transistor TR may be electrically connected to second lines LL2 connected to the second diodes DI2.

The third interconnection IT3 may be enclosed by the third insulating layer IL3. The third interconnection IT3 may be disposed on the second interconnection IT2. The third interconnection IT3 may include third plugs LP3 and third lines LL3. The third plugs LP3 may contact the second lines LL2. The third plugs LP3 may contact the top surfaces of the second lines LL2. The third plugs LP3 may be electrically connected to the second lines LL2. Each of the third plugs LP3 may have a cylindrical shape, a square pillar shape, or a tapered cylindrical shape. The third plugs LP3 may have various other shapes. The third lines LL3 may contact the third plugs LP3, respectively. The third lines LL3 may contact the top surfaces of the third plugs LP3, respectively.

In the present disclosure, the first diode DI1 may be an anti-arcing diode. The first diode DI1 and the gate electrode GE of the transistor TR may be electrically connected to any one of the first lines LL1. Therefore, as some of the charges (e.g., charges included in an etchant) injected while the second interconnection IT2 or the third interconnection IT3 is formed are transferred to the first diode DI1, a phenomenon in which the charges reach the gate insulating layer GI to damage the gate insulating layer GI may be reduced. For example, charges moving along arrow A0 may be reduced by discharging the charges to the substrate SUB along arrow A1.

In the present disclosure, the second diodes DI2 may also be anti-arcing diodes. In order to improve the effect of preventing the gate insulating layer GI from being damaged, the peripheral circuit structure PC may further include the second diodes DI2 in addition to the first diode DI1. The second diodes DI2 and the gate electrode GE of the transistor TR may be electrically connected to any one of the second lines LL2. Therefore, as some of the charges (e.g., charges included in an etchant) injected while the third interconnection IT3 is formed are transferred to the second diodes DI2, a phenomenon in which the charges damage the gate insulating layer GI may be reduced. For example, charges moving along arrow A0 may be further decreased by dispersing charges along arrow A2 as well as arrow A1.

For example, as process scaling (e.g., an increase in the density of transistors, plugs, and lines) of the semiconductor device (e.g., the semiconductor device 100 of FIGS. 1 and 2) progresses, arcing might not be sufficiently prevented by using only the first diode DI1. As in the case of the present disclosure, the peripheral circuit structure PC may further include the second diodes DI2 that are formed in an insulating layer (e.g., the first insulating layer IL1) and are floating, thus dispersing the charges to the second diodes DI2. Therefore, defects in the gate insulating layer GI of the transistor TR may be reduced through the first and second diodes DI1 and DI2.

In the present disclosure, although the second diodes DI2 are illustrated as being located at the same level as the first interconnection (e.g., the first lines LL1), this structure is only an example, and is not intended to limit the scope of the present disclosure. For example, the second diodes DI2 may be formed in the second insulating layer IL2 and may be located at the same level as the second interconnection IT2. In another example, the second diodes DI2 may be formed in the third insulating layer IL3 and may be located at the same level as the third interconnection IT3. In yet another example, the second diodes DI2 may be respectively formed in at least two of the first insulating layer IL1, the second insulating layer IL2, and the third insulating layer IL3. That is, the second diodes DI2 may be included in the scope of the present disclosure as long as they are formed in one or more of the insulating layers (e.g., IL1, IL2, and IL3) to be spaced apart from the substrate SUB.

Furthermore, in the present disclosure, although the two second diodes DI2 are illustrated as being included in the peripheral circuit structure PC, the scope of the present disclosure is not limited by the number of second diodes DI2. For example, the number of second diodes DI2 to be formed may be equal to, less than, or greater than the number of first diodes DI1.

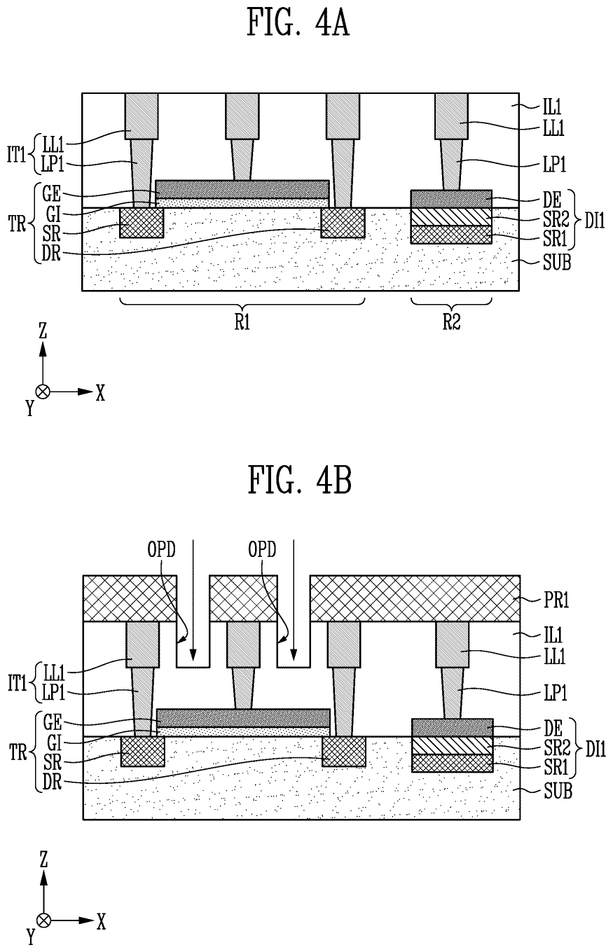

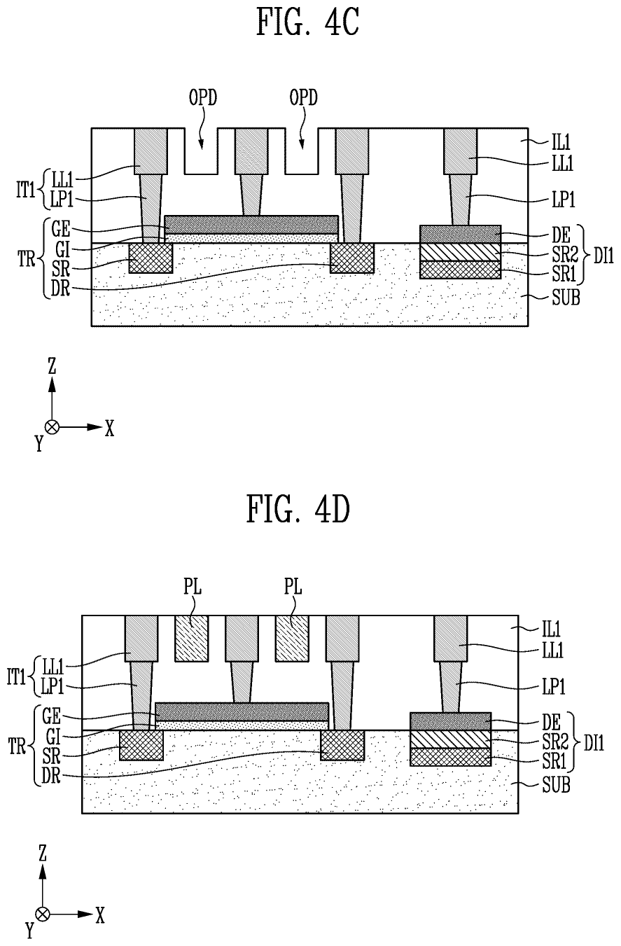

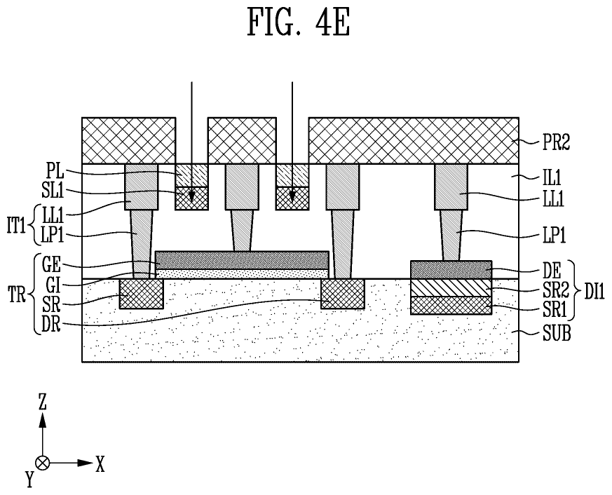

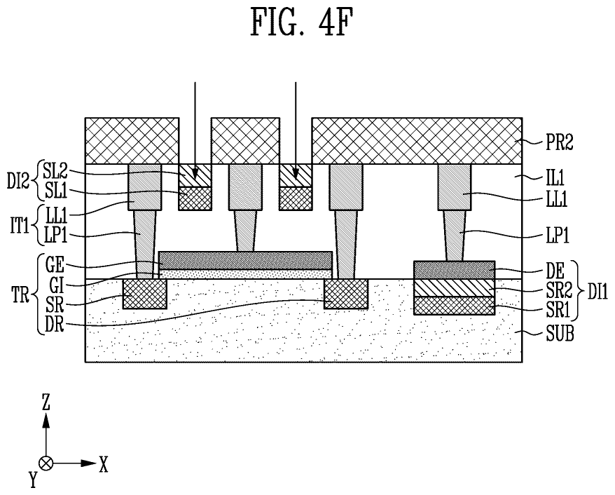

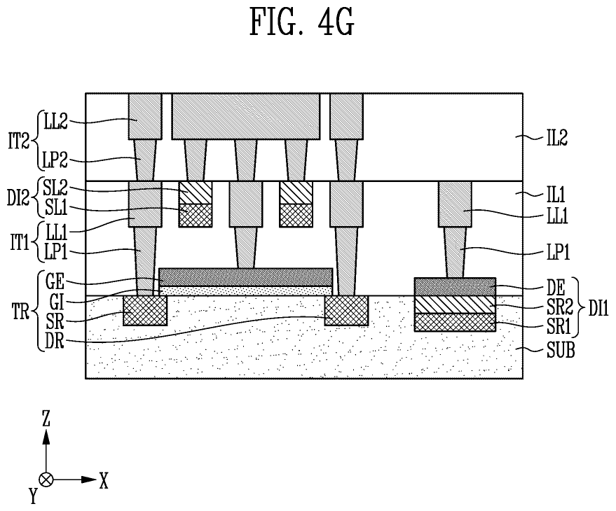

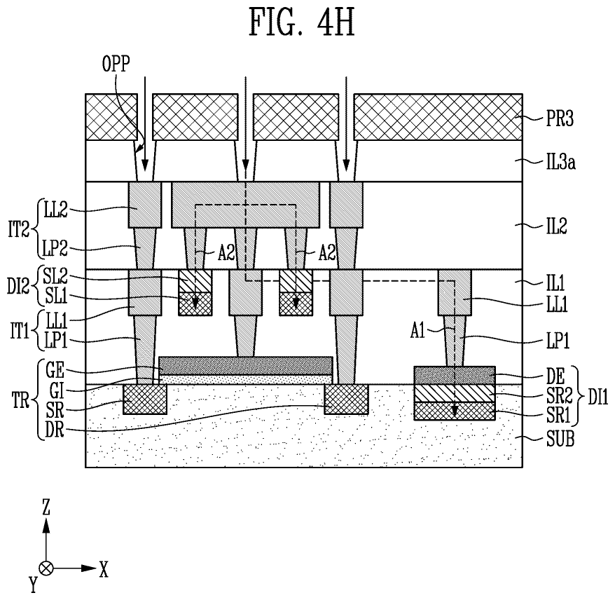

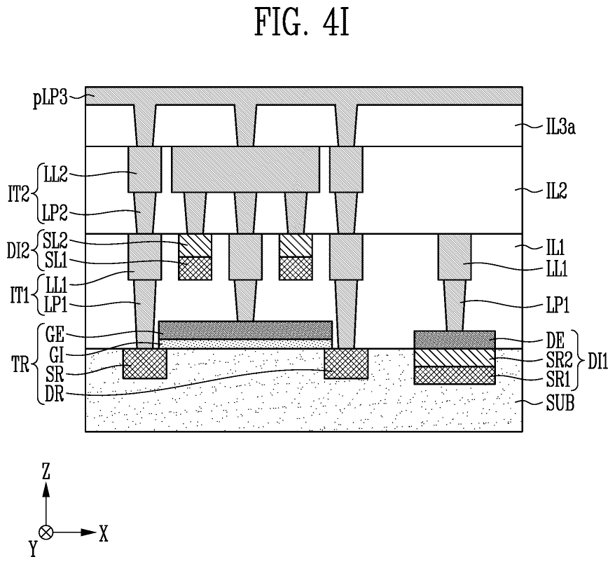

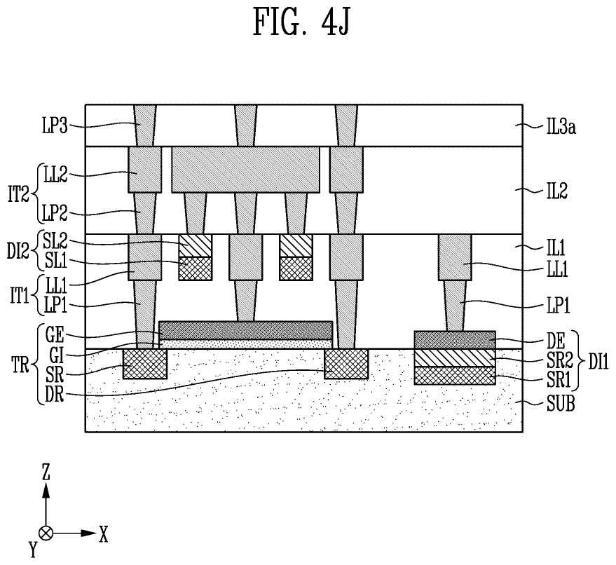

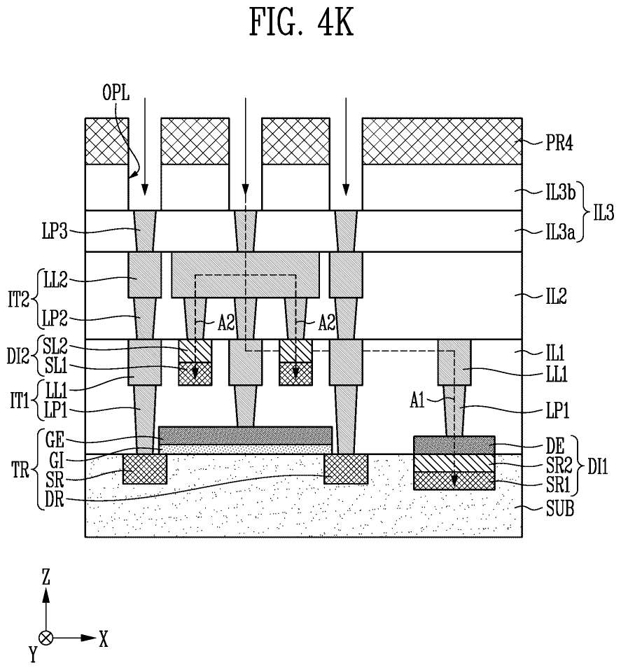

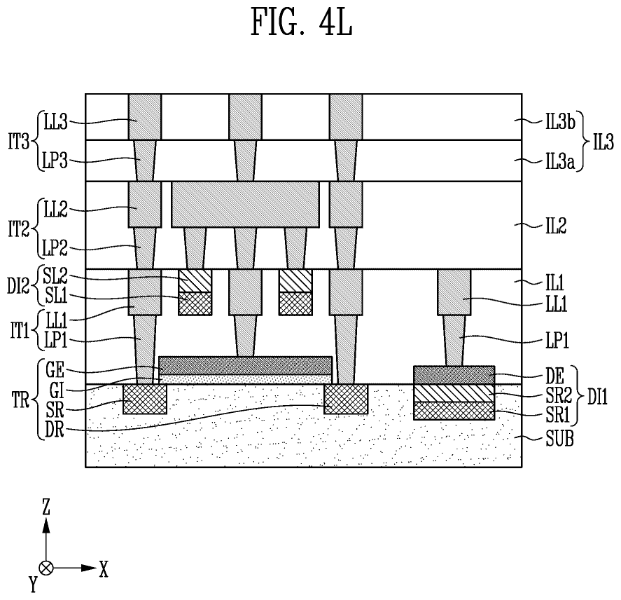

FIGS. 4A to 4L are views illustrating a method of manufacturing a peripheral circuit structure of a semiconductor device according to an embodiment of the present disclosure.

Referring to FIG. 4A, a transistor TR may be formed in a first region R1 of a substrate SUB, and a first diode DI1 may be formed in a second region R2 of the substrate SUB. For example, at least a portion of the transistor TR is formed in the first region R1 of the substrate SUB, and the other portion of the transistor TR is formed on the first region R1 of the substrate SUB. Also, at least a portion of the first diode DI1 is formed in the second region R2 of the substrate, and the other portion of the first diode DI1 is formed on the second region R2 of the substrate SUB. The first diode DI1 may be formed after the transistor TR is formed, the transistor TR may be formed after the first diode DI1 is formed, or the transistor TR and the first diode DI1 may be simultaneously formed.

The transistor TR may include a source region SR and a drain region DR that are formed in the first region R1 of the substrate SUB. The source region SR and the drain region DR may be formed by injecting impurities (e.g., impurities of an N type or a P type) into the substrate SUB. The transistor TR may include a gate insulating layer GI and a gate electrode GE that are formed on the first region R1 of the substrate SUB. The gate insulating layer GI may be formed between the source region SR and the drain region DR. For example, the gate insulating layer GI may or might not overlap with a portion of the source region SR and a portion of the drain region DR. The gate electrode GE may be formed on the gate insulating layer GI.

The first diode DI1 may include first and second semiconductor regions SR1 and SR2 formed in the second region R2 of the substrate SUB. The first semiconductor region SR1 may be formed by injecting impurities of a first type (e.g., N type) into the substrate SUB. The second semiconductor region SR2 may be formed by injecting impurities of a second type (e.g., P type) into a region on the first semiconductor region SR1. The first diode DI1 may include a diode electrode DE formed on the second region R2 of the substrate SUB. The diode electrode DE may be formed on the second semiconductor region SR2.

Subsequently, a first insulating layer IL1 and a first interconnection IT1 may be formed on the substrate SUB. The first insulating layer IL1 may cover the transistor TR and the first diode DI1. The first interconnection IT1 may penetrate the first insulating layer IL1. The first interconnection IT1 may be individually connected to the gate electrode GE, the source region SR, and the drain region DR of the transistor TR, and the diode electrode DE of the first diode DI1.

For example, a portion (e.g., the bottom) of the first insulating layer IL1 may be formed on the substrate SUB. First plugs LP1 penetrating the portion (e.g., the bottom) of the first insulating layer IL1 may be formed. The first plugs LP1 may contact the gate electrode GE, the source region SR, the drain region DR, and the diode electrode DE, respectively. The other portion (e.g., the top) of the first insulating layer IL1 covering the first plugs LP1 may be formed. First lines LL1 penetrating the other portion (e.g., the top) of the first insulating layer IL1 may be formed. The first lines LL1 may contact the first plugs LP1, respectively. For example, two or more first plugs LP1 may contact any one of the first lines LL1.

Referring to FIG. 4B, a first photoresist pattern PR1 may be formed on the first insulating layer IL1. For example, a photoresist covering the first insulating layer IL1 may be formed. The photoresist may contain a material, the chemical properties of which are changed by light. Through a process of exposing and developing the photoresist, i.e., a process of patterning the photoresist, the first photoresist pattern PR1 including an opening may be formed.

Subsequently, the first insulating layer IL1 may be etched according to the first photoresist pattern PR1. The first insulating layer IL1 may be etched by an etchant (e.g., plasma) supplied over the first photoresist pattern PR1. First openings OPD may be formed by removing a portion of the first insulating layer IL1. The first openings OPD may be spaced apart from the substrate SUB in the Z direction. For example, the first openings OPD may have a depth corresponding to at least a portion of the first interconnection IT1 (e.g., the first lines LL1) in the Z direction. Further, the first openings OPD may be spaced apart from the first interconnection IT1 in the X direction.

Referring to FIG. 4C, the first photoresist pattern PR1 on the first insulating layer IL1 may be removed.

Referring to FIG. 4D, preliminary semiconductor layers PL may be formed in the first openings OPD. The preliminary semiconductor layers PL may fill the first openings OPD. Each of the preliminary semiconductor layers PL may include polysilicon. For example, polysilicon may be deposited on the first insulating layer IL1 including the first openings OPD. A planarization process (e.g., a CMP process) may be performed on the polysilicon, whereby a portion of the polysilicon may be removed, and the remaining portion thereof may remain as the preliminary semiconductor layers PL in the first openings OPD.

Referring to FIG. 4E, a second photoresist pattern PR2 may be formed on the first insulating layer IL1. The second photoresist pattern PR2 may expose the first openings OPD.

Subsequently, impurities of a first type (e.g., N type) may be injected into lower portions of the preliminary semiconductor layers PL. The impurities of the first type may be injected into the lower portions of the preliminary semiconductor layers PL, respectively, and then first semiconductor layers SL1 may be formed.

Referring to FIG. 4F, impurities of a second type (e.g., P type) may be injected into upper portions of the preliminary semiconductor layers PL. The impurities of the second type may be injected into the upper portions of the preliminary semiconductor layers PL, respectively, and then second semiconductor layers SL2 may be formed.

As the impurities are injected into the preliminary semiconductor layers PL, second diodes DI2 may be formed in the first openings OPD, respectively. Each of the second diodes DI2 may include a first semiconductor layer SL1 and a second semiconductor layer SL2 on the first semiconductor layer SL1.

Referring to FIG. 4G, the second photoresist pattern PR2 on the first insulating layer IL1 may be removed.

Next, a second insulating layer IL2 and a second interconnection IT2 may be formed on the first insulating layer IL1. The second insulating layer IL2 may cover the first insulating layer IL1, the first interconnection IT1, and the second diodes DI2. The second interconnection IT2 may penetrate the second insulating layer IL2. The second interconnection IT2 may be individually connected to the first interconnection IT1 and the second diodes DI2.

For example, a portion (e.g., the bottom) of the second insulating layer IL2 may be formed on the first insulating layer IL1. Second plugs LP2 penetrating the portion (e.g., the bottom) of the second insulating layer IL2 may be formed. The second plugs LP2 may contact the first lines LL1 and the second diodes DI2, respectively. The other portion (e.g., the top) of the second insulating layer IL2 covering the second plugs LP2 may be formed. Second lines LL2 penetrating the other portion (e.g., the top) of the second insulating layer IL2 may be formed. The second lines LL2 may contact the second plugs LP2, respectively. For example, two or more second plugs LP2 may contact any one of the second lines LL2.

Referring to FIG. 4H, a first portion IL3a of a third insulating layer may be formed on the second insulating layer IL2. Subsequently, a third photoresist pattern PR3 may be formed on the first portion IL3a of the third insulating layer. The third photoresist pattern PR3 may partially expose the first portion IL3a of the third insulating layer.

Subsequently, the first portion IL3a of the third insulating layer may be etched according to the third photoresist pattern PR3. The first portion IL3a of the third insulating layer may be etched by an etchant supplied over the third photoresist pattern PR3. Second openings OPP may be formed by partially removing the first portion IL3a of the third insulating layer. The second openings OPP may expose portions of the top surfaces of the second lines LL2.

While the second openings OPP are formed, charges included in the etchant used for an etching process may be transferred to the first and second interconnections IT1 and IT2. The charges may be transferred to the first diode DI1 along arrow A1 and may be transferred to the second diodes DI2 along arrow A2. That is, through the first and second diodes DI1 and DI2 used as anti-arcing diodes, defects in which the charges reach the gate insulating layer DI of the transistor TR to damage the gate insulating layer DI may be reduced.

Referring to FIG. 4I, the third photoresist pattern PR3 on the first portion IL3a of the third insulating layer may be removed. Next, a conductive material pLP3 may be formed on the first portion IL3a of the third insulating layer and the second openings OPP.

Referring to FIG. 4J, a portion of the conductive material pLP3 may be removed, whereby third plugs LP3 may be formed. The third plugs LP3 may contact the second lines LL2, respectively.

Referring to FIG. 4K, a second portion IL3b of the third insulating layer may be formed on the first portion IL3a of the third insulating layer and the third plugs LP3. The first portion IL3a of the third insulating layer and the second portion IL3b of the third insulating layer may be included in the third insulating layer IL3, described above with reference to FIGS. 3A and 3B.

Subsequently, a fourth photoresist pattern PR4 may be formed on the second portion IL3b of the third insulating layer. The fourth photoresist pattern PR4 may partially expose the second portion IL3b of the third insulating layer.

Subsequently, the second portion IL3b of the third insulating layer may be etched according to the fourth photoresist pattern PR4. The second portion IL3b of the third insulating layer may be etched by an etchant supplied over the fourth photoresist pattern PR4. Third openings OPL may be formed by partially removing the second portion IL3b of the third insulating layer. The third openings OPL may expose the top surfaces of the third plugs LP3. The third openings OPL may further expose a part of the top surface of the first portion IL3a of the third insulating layer.

While the third openings OPL are formed, charges included in the etchant used for an etching process may be transferred to the first and second interconnections IT1 and IT2 and the third plugs LP3. The charges may be transferred to the first diode DI1 along arrow A1 and may be transferred to the second diodes DI2 along arrow A2. That is, through the first and second diodes DI1 and DI2 used as anti-arcing diodes, defects in which the charges reach the gate insulating layer DI of the transistor TR to damage the gate insulating layer DI may be reduced.

Referring to FIG. 4L, the fourth photoresist pattern PR4 on the third insulating layer IL3 may be removed. Subsequently, third lines LL3 may be formed in the third openings OPL. The third plugs LP3 and the third lines LL3 may be included in a third interconnection IT3.

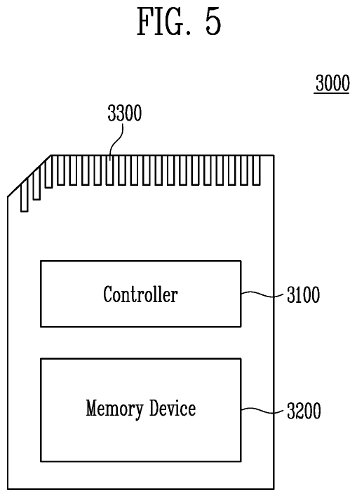

FIG. 5 is a diagram illustrating a memory card system to which a semiconductor device according to the present disclosure is applied.

Referring to FIG. 5, a memory card system 3000 may include a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200 or may control a background operation of the memory device 3200. The controller 3100 may provide an interface between the memory device 3200 and a host. The controller 3100 may run firmware that controls the memory device 3200. In an example, the controller 3100 may include components, such as a random access memory (RAM), a processor, a host interface, a memory interface, and an error corrector.

The controller 3100 may communicate with an external device through the connector 3300. The controller 3100 may communicate with an external device (e.g., a host) based on a specific communication standard. For example, the controller 3100 may communicate with the external device through at least one of various communication standards, such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be defined by at least one of the above-described various communication standards.

The memory device 3200 may include a plurality of memory cells and may be configured in the same manner as the semiconductor device 100 illustrated in FIG. 1.

The controller 3100 and the memory device 3200 may be integrated into a single semiconductor device to form a memory card. For example, the controller 3100 and the memory device 3200 may be integrated into a single semiconductor device and may then form a memory card, such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

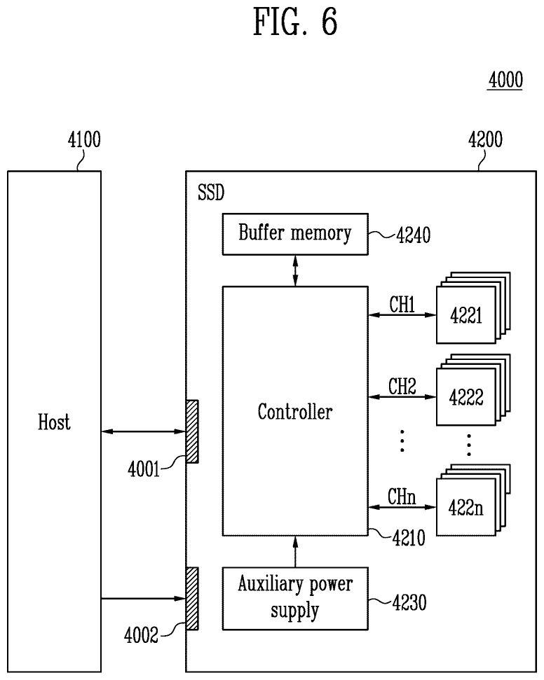

FIG. 6 is a diagram illustrating a solid state drive (SSD) system to which a semiconductor device according to the present disclosure is applied.

Referring to FIG. 6 an SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the received signals may be signals based on the interfaces of the host 4100 and the SSD 4200. For example, the signals may be defined by at least one of various interfaces, such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells configured to store data. Each of the memory devices 4221 to 422n may be configured in the same manner as the semiconductor device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located in a main board and may provide auxiliary power to the SSD 4200.

The buffer memory 4240 may function as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories, such as a dynamic random access memory (DRAM), a synchronous DRAM (SDRAM), a double data rate (DDR) SDRAM, and a low power DDR (LPDDR) SDRAM, or nonvolatile memories, such as a ferroelectric RAM (FRAM), a resistive RAM (ReRAM), a spin transfer torque magnetic RAM (STT-MRAM), and a phase-change RAM (PRAM).

The present disclosure may reduce damage to a peripheral circuit structure by changing the configuration of the peripheral circuit structure.

What is claimed is:

1. A semiconductor device, comprising:
a substrate including a first region and a second region;
a transistor including a gate insulating layer and a gate electrode, stacked over the first region of the substrate;
a first diode, at least a portion of the first diode being formed in the second region of the substrate;
an insulating layer disposed on the substrate;
a second diode disposed in the insulating layer to be spaced apart from the substrate; and
interconnections connected to the first diode, the second diode, and the gate electrode, respectively.

2. The semiconductor device according to claim 1, wherein the interconnections comprise:
a first interconnection configured to electrically connect the gate electrode to the first diode; and
a second interconnection configured to electrically connect the first interconnection to the second diode.

3. The semiconductor device according to claim 2, wherein the first interconnection comprises:
first plugs contacting the gate electrode and the first diode, respectively; and
a first line contacting the first plugs.

4. The semiconductor device according to claim 3, wherein the first diode comprises:
a first semiconductor region formed in the second region of the substrate;
a second semiconductor region formed in the second region of the substrate and disposed on the first semiconductor region; and
a diode electrode stacked over the second region of the substrate and disposed on the second semiconductor region,
wherein, among the first plugs, a first plug contacting the first diode contacts the diode electrode.

5. The semiconductor device according to claim 3, wherein the insulating layer includes a first insulating layer enclosing the first plugs and the first line.

6. The semiconductor device according to claim 3, wherein the second diode is located at a level identical to a level at which the first plugs or the first line is located.

7. The semiconductor device according to claim 3, wherein the second diode is disposed to be spaced apart from the first plugs and the first line.

8. The semiconductor device according to claim 3, wherein the second interconnection comprises:
second plugs contacting the first line and the second diode, respectively; and
a second line contacting the second plugs.

9. The semiconductor device according to claim 8, wherein the insulating layer includes a second insulating layer enclosing the second plugs and the second line.

10. The semiconductor device according to claim 1, wherein the second diode comprises:
a first semiconductor layer disposed in the insulating layer; and
a second semiconductor layer disposed on the first semiconductor layer.

11. The semiconductor device according to claim 10,
wherein the first semiconductor layer includes an impurity of a first type, and
wherein the second semiconductor layer includes an impurity of a second type, the second type being different from the first type.

12. The semiconductor device according to claim 1, wherein the second diode is disposed to be spaced apart from the transistor and the first diode.

13. A method of manufacturing a semiconductor device, comprising:
forming a transistor including a gate insulating layer and a gate electrode that are stacked over a first region of a substrate;
forming a first diode, wherein at least a portion of the first diode is formed in a second region of the substrate;
forming a first insulating layer that covers the transistor and the first diode on the substrate;
forming a first interconnection that penetrates the first insulating layer, the first interconnection connecting the gate electrode to the first diode;
forming a second diode in the first insulating layer; and
forming a second interconnection that connects the first interconnection to the second diode.

14. The method according to claim 13, wherein forming the first diode comprises:
forming a first semiconductor region by injecting an impurity of a first type into the second region of the substrate;
forming a second semiconductor region by injecting an impurity of a second type, the second type being different from the first type, into a region on the first semiconductor region; and
forming a diode electrode over the second region of the substrate.

15. The method according to claim 14, wherein forming the first interconnection comprises:
forming first plugs that contact the gate electrode and the diode electrode, respectively; and
forming a first line that individually contacts the first plugs.

16. The method according to claim 13, wherein forming the second diode in the first insulating layer comprises:
forming a first opening spaced apart from the substrate and the first interconnection by removing a portion of the first insulating layer; and
forming the second diode in the first opening.

17. The method according to claim 16, wherein forming the first opening comprises:
forming the first opening to have a level identical to a level of at least a portion of the first interconnection.

18. The method according to claim 16, wherein forming the second diode in the first opening comprises:
filling the first opening with a preliminary semiconductor layer;
forming a first semiconductor layer by injecting an impurity of a first type into a lower portion of the preliminary semiconductor layer; and
forming a second semiconductor layer by injecting an impurity of a second type, the second type being different from the first type, into an upper portion of the preliminary semiconductor layer.

19. The method according to claim 13, further comprising, after forming the second interconnection:
forming a third interconnection connected to the second interconnection.

20. The method according to claim 19, wherein, in forming the third interconnection, a charge used to form the third interconnection is transferred to the first diode and the second diode.
